(19) United States
(12) Patent Application Publication
(10) Pub. No.: US 2025/0374799 A1
(43) Pub. Date: Dec. 4, 2025

(54) DISPLAY DEVICE, ELECTRONIC DEVICE, AND METHOD FOR MANUFACTURING THE DISPLAY DEVICE

(71) Applicant: Samsung Display Co., Ltd., Yongin-si (KR)

(72) Inventors: HYUNKYUNG YUN, Yongin-si (KR); SANGDUK LEE, Yongin-si (KR)

(21) Appl. No.: 19/212,049

(22) Filed: May 19, 2025

(30) Foreign Application Priority Data
May 28, 2024 (KR) 10-2024-0069501

(51) Int. Cl. H10K 59/80; H10K 59/12

(52) U.S. Cl. CPC H10K 59/872; H10K 59/1201; H10K 59/8792; H10K 59/8793

(57) ABSTRACT

A display device includes a display panel including a display region and a non-display region surrounding the display region, a polarizing unit disposed on the display panel and covering the display panel, when viewed in a plan view, a coating window directly disposed on the polarizing unit and including a resin material cured by irradiating the resin material with light, and the coating window includes a first layer directly disposed on the polarizing unit and including a first photoinitiator which reacts with light having a first wavelength, and a second layer directly disposed on the first layer and including a second photoinitiator which reacts with light having a second wavelength shorter than the first wavelength.

This application claims priority to Korean Patent Application No. 10-2024-0069501, filed on May 28, 2024, and all the benefits accruing therefrom under 35 U.S.C. § 119, the content of which in its entirety is herein incorporated by reference.

### BACKGROUND

### Field

Embodiments of the present disclosure described herein relate to a display device and a method for manufacturing the display device, and more particularly, relate to a display device including a coating window.

### Description of the Related Art

A display device, such as, for example, a television, a monitor, a smartphone, and a table, includes a display panel, to display an image. As the display panel, various display panels, such as, for example, a liquid crystal display panel, an organic light emitting display panel, an electro-wetting display panel, and an electrophoretic display panel have been developed. In some aspects, the display device may include a window to protect the display panel. The window may be attached to the display panel through a lamination process.

### SUMMARY

Embodiments of the present disclosure provide a display device having an improved physical characteristic as a coating layer is applied to a rear surface of a coating window and cured, by utilizing the coating window provided in multiple layers including photoinitiators reacting with light having different respective wavelengths, and a method for fabricating the same.

According to an embodiment of the present disclosure, a display device includes a display panel including a display region and a non-display region surrounding the display region, a polarizing unit disposed on the display panel and covering the display panel, when viewed in a plan view, and a coating window directly disposed on the polarizing unit and including a resin material cured by irradiating the resin material with light, and the coating window includes a first layer directly disposed on the polarizing unit and including a first photoinitiator which reacts with light having a first wavelength, and a second layer directly disposed on the first layer and including a second photoinitiator which reacts with light having a second wavelength shorter than the first wavelength.

The second layer may have a thickness equal to or greater than a thickness of the first layer.

The coating window may include a third layer directly disposed on the second layer and including a third photoinitiator which reacts with light having a third wavelength shorter than the second wavelength.

The third layer may have a thickness equal to or greater than a thickness of the second layer.

A ratio among a thickness of the first layer, a thickness of the second layer, and a thickness of the third layer may be about 1:2:3.

A thickness of the first layer, a thickness of the second layer, and a thickness of the third layer may be substantially equal to each other.

The first wavelength of the light which the first photoinitiator reacts with may range from about 320 nm to about 400 nm, and the second wavelength of the light which the second photoinitiator reacts with may range from about 280 nm to about 320 nm.

The third photoinitiator may react with light having a wavelength of about 280 nm or less.

The polarizing unit may include a first polarizing part overlapped with the display panel when viewed in the plan view, and a second polarizing part extending from the first polarizing part and having an outer side surface protruding further outward compared to an outer side surface of the display panel.

The display device may further include a light blocking pattern directly disposed on the polarizing unit and corresponding to the non-display region, and the coating window may directly contact the light blocking pattern and cover the light blocking pattern.

The coating window may have a light transmittance of at least about 90% with respect to light of whole wavelengths.

The coating window may have a pencil hardness of at least 9H.

A curing rate of the first layer, a curing rate of the second layer, and a curing rate of the third layer may each be at least about 90%.

The coating window may have a thickness ranging from about 600 μm to about 1000 μm.

An elastic modulus of the coating window may be at least about 800 Mpa.

According to an embodiment of the present disclosure, a method for manufacturing a display device includes preparing a preliminary display device including a display panel and a polarizing unit disposed on the display panel, wherein the display panel includes a display region and a non-display region surrounding the display region, applying a first coating liquid on the polarizing unit, wherein the first coating liquid includes a first photoinitiator and a resin material curable by irradiating the resin material with light, and the first photoinitiator reacts with light having a first wavelength, forming a first preliminary coating layer by pre-curing the first coating liquid, applying a second coating liquid on the first preliminary coating layer, wherein the second coating liquid includes a second photoinitiator and the resin material, and the second photoinitiator reacts with light having a second wavelength shorter than the first wavelength, forming a second preliminary coating layer by pre-curing the second coating liquid, and forming a first layer and a second layer by performing a main curing with respect to the first preliminary coating layer and the second preliminary coating layer.

The method for manufacturing the display device may include applying a third coating liquid on the second preliminary coating layer, wherein the third coating liquid includes a third photoinitiator and the resin material, and the third photoinitiator reacts with light having a third wavelength shorter than the second wavelength, forming a third preliminary coating layer by pre-curing the third coating liquid, and the main curing is performed further with respect to the third preliminary coating layer and forms a third layer.

Light having energy of about 100 mJ or less may be utilized in each of the pre-curing of the first coating liquid and the pre-curing of the second coating liquid, and light having energy of about 1,200 mJ or more may be utilized in the main curing.

The second layer may have a thickness equal to or greater than a thickness of the first layer.

The third layer may have a thickness equal to or greater than the thickness of the second layer.

According to an embodiment of the present disclosure, an electronic device includes a display module, and a coating window including a resin material cured by irradiating the resin material with light and disposed on the display module, wherein the display module includes a display panel including a display region and a non-display region surrounding the display region, and a polarizing unit disposed on the display panel and covering the display panel, when viewed in a plan view, and the coating window includes a first layer directly disposed on the polarizing unit and including a first photoinitiator which reacts with light having a first wavelength, and a second layer directly disposed on the first layer and including a second photoinitiator which reacts with light having a second wavelength shorter than the first wavelength.

### BRIEF DESCRIPTION OF THE DRAWINGS

The above and other objects and features of the present disclosure will become apparent by describing in detail embodiments thereof with reference to the accompanying drawings.

FIG. 1 is a perspective view of a display device according to an embodiment of the present disclosure.

FIG. 2 is an exploded perspective view of a display device, according to an embodiment of the present disclosure.

FIG. 3 is a plan view of a display panel according to an embodiment of the present disclosure.

FIG. 4 is a cross-sectional view of a display device according to an embodiment of the present disclosure.

FIG. 5 is a cross-sectional view illustrating an enlarged region AA′ of FIG. 4 according to an embodiment of the present disclosure.

FIGS. 6A to 6H are cross-sectional views partially illustrating a method for manufacturing a display device according to an embodiment of the present disclosure.

### DETAILED DESCRIPTION

In this specification, it will be understood that, when a component is referred to as being “on”, “connected to”, “coupled” to another component, it can be directly disposed on/connected to/coupled to/the another component or a third intervening component may be present therebetween.

The same reference numeral will be assigned to the same component. In some aspects, in drawings, thicknesses, proportions, and dimensions of components may be exaggerated to describe the technical features effectively. The term “and/or” includes any and all combinations of one or more of associated components.

Although the terms “first”, “second”, and the like may be used to describe various components, the components should not be construed as being limited by the terms. The terms are used to distinguish one component from another component. For example, a first component discussed below could be termed a second component without departing from the technical scope of the present disclosure. Similarly, the second component could be termed the first component. The singular forms are intended to include the plural forms unless the context clearly indicates otherwise.

In some aspects, the terms “under”, “at a lower portion”, and “an upper portion” are used to describe the relationship between components illustrated in drawings. The terms are relative and are described with reference to a direction indicated in the drawing.

It will be further understood that the terms “comprises”, “comprising”, “includes”, or “including”, or “having” specify the presence of stated features, numbers, steps, operations, components, parts, or the combination thereof, but do not preclude the presence or addition of one or more other features, numbers, steps, operations, components, components, and/or the combination thereof.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical terms and scientific terms) used in the specification have the same meaning as commonly understood by one skilled in the art to which the present disclosure belongs. Furthermore, terms such as, for example, terms defined in the dictionaries commonly used should be interpreted as having a meaning consistent with the meaning in the context of the related technology, and should not be interpreted in ideal or overly formal meanings unless explicitly defined herein.

Hereinafter, embodiments according to the present disclosure will be described.

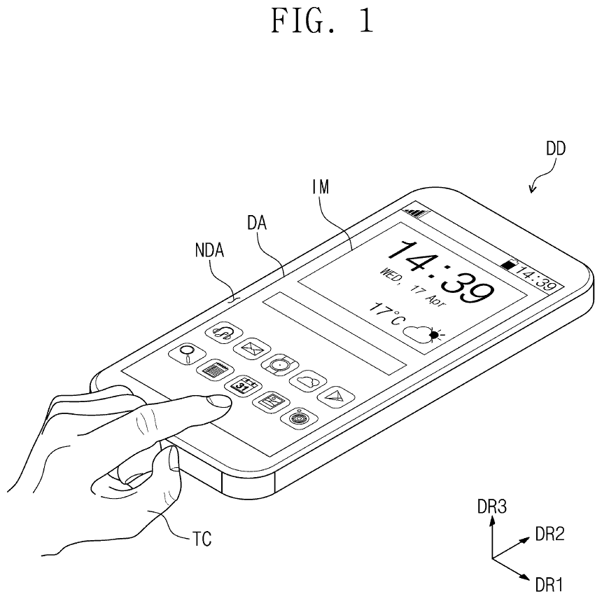

FIG. 1 is a perspective view of a display device DD according to an embodiment of the present disclosure.

Referring to FIG. 1, according to an embodiment of the present disclosure, a portable terminal is illustrated as the example of the display device DD. The portable terminal may include a tablet PC, a smartphone, a personal digital assistant (PDA), a portable multimedia player (PMP), a game console, and a wristwatch-type electronic device. However, embodiments of the present disclosure are not limited thereto.

The display device DD according to the present disclosure may be used for small and medium-size electronic devices, such as, for example, a personal computer, a notebook computer, a car navigation unit, and a camera, in addition to large-size electronic devices, such as, for example, a television or an outside billboard. The above examples are provided as example embodiments, and it is to be understood that the display device DD may be applied to any other electronic device(s) without departing from the concept of the present disclosure.

The display device DD may be flexible. The wording “flexible” refers to a bendable characteristic, and the flexible structure may include all structures ranging from a fully folded structure to a structure bent at a level of several nanometers. For example, the display device DD (a flexible display device) which is flexible may include a curved display device, a foldable display device, a slidable display device, or a rollable display device. However, embodiments of the present disclosure are not limited thereto. For example, the display device DD may be rigid.

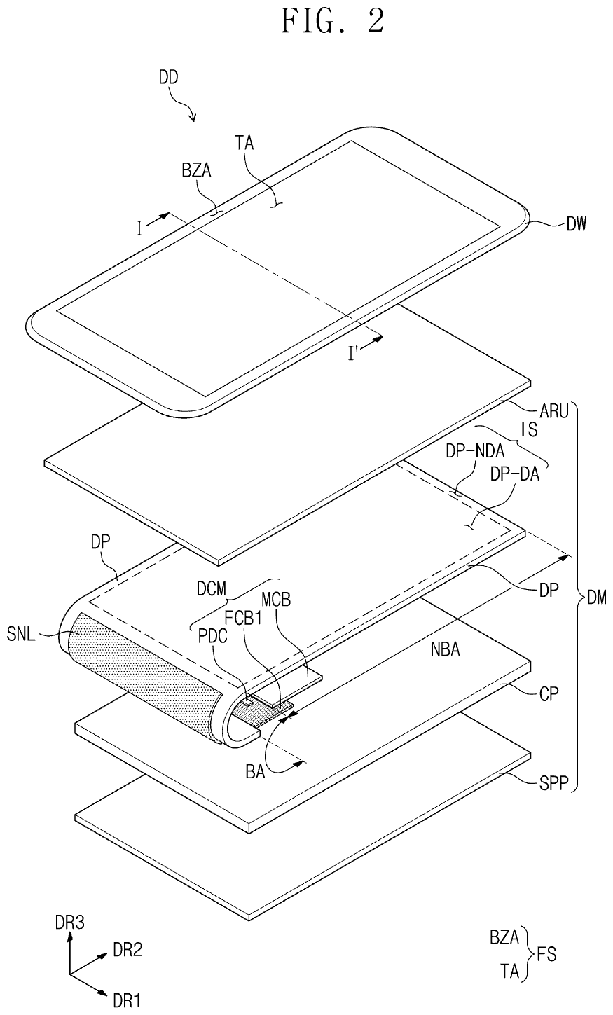

As illustrated in FIG. 1, a display surface for displaying an image IM1 is parallel to a plane defined by a first direction DR1 and a second direction DR2. The display device DD may include a plurality of regions divided on the display surface. The display surface includes a display region DA for displaying the image IM and a non-display region NDA adjacent to the display region DA. The non-display region NDA may correspond to a bezel region BZA (see FIG. 2). For example, the display region DA may have a rectangular shape. The non-display region NDA surrounds the display region DA. In some aspects, although not illustrated, the display device DD may include a shape partially curved. Accordingly, one region of the display region DA may have the shape curved.

A front surface (or top surface) and a rear surface (bottom surface) of each of members constituting the display device DD are opposite to each other in the third direction DR3, and a normal direction to the front surface and the rear surface may substantially parallel to the third direction DR3. The distance between the front surface and the rear surface defined in the third direction DR3 may correspond to the thickness of a member (or unit). In this specification, the wording “in a plan view” may refer to the state when viewed in the third direction DR3. In this specification, the term “in a cross-sectional view” may indicate a state when viewed in the first direction DR1 or the second direction DR2. The directions indicated by the first direction DR1, the second direction DR2, and the third direction DR3 may be relative concepts and may be changed to different directions. In this specification, the wording “overlapped” may refer to “overlapped when viewed in a plan view” unless specified otherwise.

A front surface (or a top surface or a first surface) and a rear surface (or a bottom surface or a second surface) of each of members are defined based on a direction in which the image IM is displayed. The directions indicated by the first direction DR1, the second direction DR2, and the third direction DR3 may be relative concepts and may be changed to different directions. Hereinafter, the first to third directions are indicated by the first direction to the third direction DR1, DR2, and DR3, respectively, and refer to the same reference numerals.

According to the present disclosure, the display device DD may sense a touch input TC by a user applied from the outside. The touch input TC by the user may include various external inputs, such as, for example, inputs made by a part of a physical body of the user, light, heat, or pressure. According to the present embodiment, the following description will be made on the assumption that the input of the user is made by a hand of the user on the front surface, but this is provided for example illustrative purposes. As described herein, the touch input TC by the user may be provided in various forms. In some aspects, the display device DD may sense the input by the user applied to a side surface or a rear surface of the display device DD, depending on the structure of the display device DD. The present disclosure is not limited to any one embodiment.

FIG. 2 is an exploded perspective view of the display device DD according to an embodiment of the present disclosure.

Referring to FIG. 2, the display device DD may include a coating window DW and a display module DM. The coating window DW may be disposed on a polarizing unit ARU. In this case, the wording “directly disposed” may refer to placement without an additional adhesion or adhesive layer.

The coating window DW may be provided on a front surface FS of the display device DD. The front surface FS of the coating window DW may include a transmission region TA and a bezel region BZA. The transmission region TA of the coating window DW may be a region optically transparent. The coating window DW may transmit the image IM, which is provided by the display panel DP, through the transmission region TA, and the user may view the image IM (see FIG. 1).

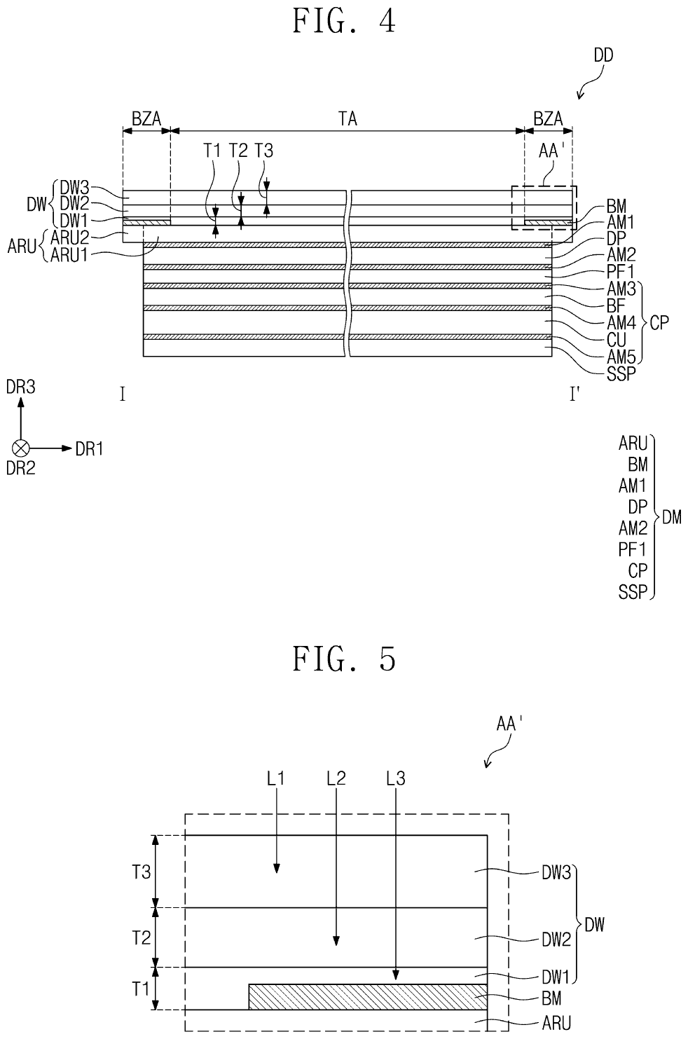

The bezel region BZA of the coating window DW may be overlapped with a light blocking pattern BM (see FIG. 4) to be described herein. The light blocking pattern BM may include a material including a specific color to block light. The bezel region BZA of the coating window DW may prevent one component, which is overlapped with the light blocking pattern BM (see FIG. 4), of the display panel DP from being viewed from the outside.

The bezel region BZA may be adjacent to the transmission region TA. The shape of the transmission region TA may be substantially defined by the bezel region BZA. For example, the bezel region BZA may be disposed outside the transmission region TA and surround the transmission region TA. However, this is provided for example illustrative purposes, and the bezel region BZA may be disposed such that the bezel region BZA is adjacent to a single side of the transmission region TA or may be omitted. In some aspects, the bezel region BZA may be disposed on a side surface of the display device DD instead of the front surface of the display device DD.

The coating window DW may include an optically transparent insulating material. The coating window DW may include a resin material which may be cured by irradiating the resin material with a laser beam. The coating window DW may have a single structure or a multi-layer structure. Regarding the display device DD including the coating window DW according to the present disclosure, as a lamination process may be omitted, the manufacturing process of the display device DD may be simplified and the costs may be reduced.

The coating window DW may include a functional coating layer, such as, for example, an anti-fingerprint layer, an anti-reflection layer, or a hard coating layer. According to the present embodiment, although the coating window DW in a flat form is illustrated in a display region DP-DA, the coating window DW may have various shapes. Edges, which face each other in the first direction DR1, of the coating window DW may provide curved surfaces.

The display module DM may be provided on the rear surface of the coating window DW to generate an image. In some aspects, the display module DM may sense the touch input TC (see FIG. 1) by the user.

Although the display module DM is provided as having a flat display surface for example illustrative purposes, the shape of the display module DM may be modified. The edges, which face each other in the first direction DR1, of the display module DM may provide curved surfaces, as the central portion of the display module DM is bent.

The display module DM may include a polarizing unit ARU, the display panel DP, a protective panel CP, a support panel SSP, and a driving control module DCM.

The polarizing unit ARU may be interposed between the display panel DP and the coating window DW. The polarizing unit ARU may reduce the reflectance of light incident thereto from the outside. The polarizing unit ARU may include at least one of a retarder, a polarizer, a polarizing film, and a polarizing filter. The polarizing unit ARU may be attached to the display panel DP through an adhesive layer. However, the type of the polarizing unit ARU is provided for example illustrative purposes, and embodiments of the present disclosure are not limited thereto. For example, the polarizing unit ARU may include a color filter.

The display panel DP may be interposed between the coating window DW and the support panel SSP. The display panel DP may display an image in response to an electrical signal. The display panel DP according to an embodiment may be an emissive-type display panel, but is not particularly limited thereto. For example, the display panel DP may be an organic light emitting display panel, an inorganic light emitting display panel, an organic-inorganic display panel or a quantum dot light emitting display panel. A light emitting layer of the organic light emitting display panel may include an organic light emitting material, and a light emitting layer of the inorganic light emitting display panel may include an inorganic light emitting material. A light emitting layer of the organic-inorganic light emitting display layer may include an organic-inorganic light emitting material. A light emitting layer of the quantum dot light emitting display panel may include a quantum dot and a quantum rod.

The display panel DP may include a non-bending region NBA, and a bending region BA bent while extending from an end portion of the non-bending region NBA. The bending region BA may extend in a direction opposite to the second direction DR2 from the non-bending region NBA. The bending region BA may be bent to face a rear surface of the non-bending region NBA. However, the form of the display panel DP is not limited thereto. For example, the form of the display panel DP may be the form of a rigid substrate having no bending region BA. For example, the display panel DP may be formed on the rigid substrate, and a first circuit board FCB1 may be bent between the display panel DP and a main circuit board MCB to connect the display panel DP to the main circuit board MCB.

The image IM (see FIG. 1) provided by the display device DD may be displayed on the front surface IS of the display panel DP. The front surface IS of the display panel DP may include a display region DP-DA and a non-display region DP-NDA surrounding the display region DP-DA. In this case, the display region DP-DA may correspond to the display region DA of FIG. 1, and the non-display region DP-NDA may correspond to the non-display region NDA of FIG. 1. The non-display region DP-NDA may correspond to the bezel region BZA of FIG. 2.

A bending protecting layer SNL may be disposed on the display panel DP and may be bent together with the bending region BA. The bending protecting layer SNL may prevent the bending portion of the display panel DP from being damaged due to external shock or prevent external foreign substances from being introduced into the bending portion of the display panel DP. The bending protecting layer SNL illustrated in the drawing is provided only for the illustrative purpose, and may have various shapes as applicable or suitable in accordance with one or more embodiments of the present disclosure. In some aspects, when the display panel DP does not include the bending portion, the bending protecting layer SNL may be omitted.

The display region DP-DA may be activated in response to an electrical signal to display an image. According to an embodiment, the display region DP-DA of the display panel DP may correspond to the transmission region TA of the coating window DW. In this specification, the wording “a region/part correspond to a region/part” refers to that “the region/part is overlapped with the region/part”, which does not refer to that the regions/parts are the same as in area and/or shape.

The non-display region DP-NDA may be adjacent to the outer portion of the display region DP-DA. For example, the non-display region DP-NDA may surround the display region DP-DA. However, embodiments of the present disclosure are not limited thereto, and the non-display region DP-NDA may be defined in various shapes.

The non-display region DP-NDA may be a region for disposing a driving circuit, a driving line, various signal lines which provide the electrical signal, or pads for driving elements disposed in the display region DP-DA. The non-display region DP-NDA of the display panel DP may correspond to the bezel region BZA of the coating window DW. Components of the display panel DP, which is disposed in the non-display region DP-NDA, may be prevented from being viewed to the outside by the bezel region BZA.

The driving control module DCM includes the main circuit board MCB (or the driving circuit substrate), the first circuit board FCB1 (or a panel flexible circuit substrate), and a panel driving circuit PDC. The first circuit board FCB1 may be connected to an end portion of the display panel DP to electrically connect the main circuit board MCB to the display panel DP.

The first circuit board FCB1 may electrically connect the main circuit board MCB to the display panel DP, such that the panel driving circuit PDC is mounted on the first circuit board FCB1. This refers to the panel driving circuit PDC being mounted in the type of chip on film (COF). The panel driving circuit PDC may be implemented in the form of an integrated circuit. Although not illustrated separately, a plurality of passive elements and a plurality of active elements may be mounted on the main circuit board MCB. The main circuit board MCB may be a rigid circuit board or a flexible circuit board, and the first circuit board FCB1 may be a flexible circuit board. The main circuit board MCB may be positioned on the rear surface of the display panel DP.

The protective panel CP may be disposed on a rear surface of the display panel DP to protect the display panel DP from impact. The protective panel CP may include a plastic film serving as a base layer. The protective panel CP may have a single layer structure or a multi-layer structure.

The support panel SSP may be disposed on a rear surface of the protective panel CP and support the display panel DP and the protective panel CP. The support panel SSP may be a metal plate having strength stronger than standard strength. The support panel SSP may be a stainless steel plate. The support pane SSP may have black color to block external light incident to the display panel DP.

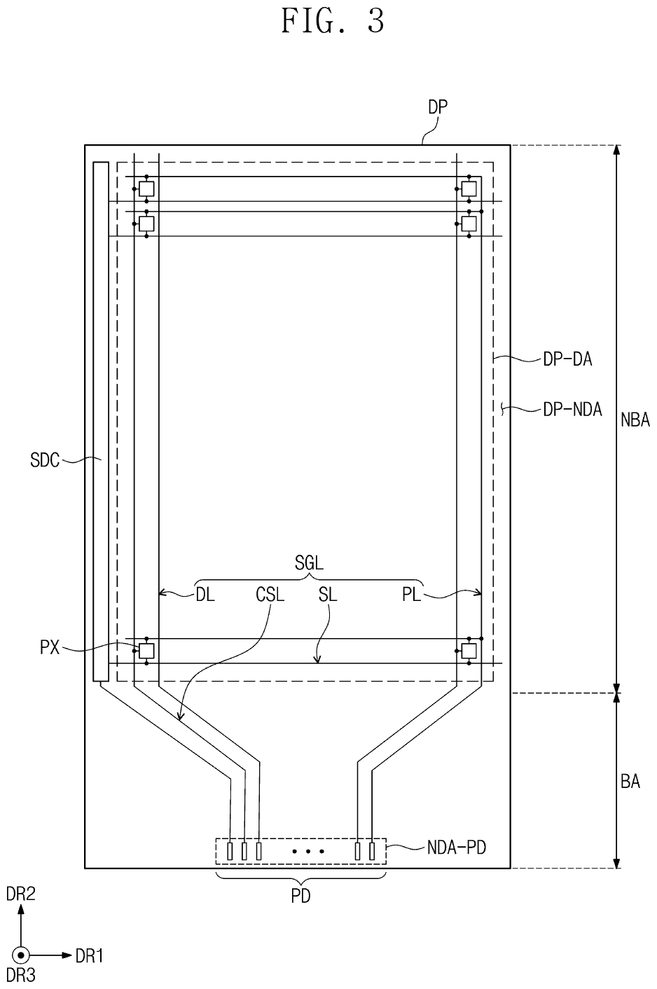

FIG. 3 is a plan view illustrating the display panel DP according to an embodiment of the present disclosure.

FIG. 3 is a circuit diagram for a signal. In some aspects, partial components are omitted for the convenience of explanation in FIG. 3.

Referring to FIG. 3, the display panel DP may include a display region DP-DA and a non-display region DP-NDA when viewed in a plan view. According to the present embodiment, the non-display region DP-NDA may be defined along the edge of the display region DP-DA. The display region DP-DA and the non-display region NP-NDA of the display panel DP may correspond to the display region DA and the non-display region NDA of the display device DD illustrated in FIG. 1.

The display panel DP may include the non-bending region NBA, and the bending region BA bent while extending from an end portion of the non-bending region NBA. However, the bending region BA of the display panel DP may be omitted as applicable or suitable in accordance with one or more embodiments of the present disclosure.

The display panel DP may include a scan driving circuit SDC, a plurality of signal lines SGL (hereinafter, signal lines), a plurality of signal pads PD (hereinafter, signal pads), and a plurality of pixels PX (hereinafter, pixels). The pixels PX are disposed in the display region DP-DA. Each of the pixels PX includes an organic light emitting diode and a pixel driving circuit connected to the organic light emitting diode.

The scan driving circuit SDC generates a plurality of scan signals (hereinafter, “scan signals”) and sequentially outputs the scan signals to a plurality of scan lines (hereinafter, “scan lines”) to be described later. The scan driving circuit SDC may further output another control signal to driving circuits for the pixels PX.

The scan driving circuit SDC may include a plurality of transistors formed through a process, such as, for example, a low temperature polycrystalline silicon (LTPS) process or a low temperature polycrystalline oxide (LTPO) process, the same as the process for the pixel driving circuit for the pixels PX.

The signal lines SGL include scan lines GL, data lines DL, a power line PL, and a control signal line CSL. Each of the scan lines GL is connected to a relevant pixel PX of the pixels PX, and each of the data lines DL is connected to a relevant pixel PX of the pixels PX. The power line PL is connected to the pixels PX. The control signal line CSL may provide control signals to the scanning driving circuit SDC.

The signal lines SGL may be overlapped with the display region DP-DA and the non-display region DP-NDA. The signal lines SGL may include a pad part and a line part. The line part may be overlapped with the display region DP-DA and the non-display region DP-NDA. The pad part is connected to an end of the line part. The pad part is disposed in the non-display region NP-NDA, and is overlapped with a relevant signal pad of the signal pads PD. The region for the signal pads PD in the non-display region DP-NDA may be defined as a pad region NDA-PD.

Actually, the line part connected to the pixel PX constitutes the most part of the signal lines SGL. The line part is connected to transistors (not illustrated) of the pixel PX. The line part may have a single-layer/multi-layer structure. The line part may have the form of a single body, or may include at least two portions. The at least two portions may be disposed at mutually different layers, and may be connected to each other through a contact hole formed through an insulating layer interposed between the at least two portions.

FIG. 4 is a cross-sectional view of the display device DD according to an embodiment of the present disclosure. In more detail, FIG. 4 is a cross-sectional view taken along line I-I′ of FIG. 2.

Although the display panel DP is expressed as a single layer in FIG. 4, the display panel DP may have a multi-layer structure. The display panel DP may include a base layer, a circuit layer, a light emitting element layer, and an encapsulating layer. In some aspects, it may be obvious to those skilled in the art, to which the present disclosure pertains, the display panel DP may further include other general-purpose components.

Referring to FIG. 4, the stack structure of the display device DD is illustrated. The display device DD may include the display module DM and the coating window DW disposed on the display module DM. The display module DM may include the display panel DP, the polarizing unit ARU, a first protective layer PF1, the protective panel CP, the support panel SSP, and first and fifth adhesive layers AM1 to AM5.

The first to fifth adhesive layers AM1 to AM5 to be described herein may be a pressure sensitive adhesive film (PSA), an optically clear adhesive film (OCA), or an optically clear resin (OCR). The first to fifth adhesive layers AM1 to AM5 include a photo-curable adhesive material or a thermosetting adhesive material, but the materials of the first to fifth adhesive layers AM1 to AM5 are not particularly limited. Some of the first to fifth adhesive layers AM1 to AM5 may be omitted.

The polarizing unit ARU may be disposed on a top surface of the display panel DP. The polarizing unit ARU may cover the display panel DP when viewed in a plane view. The polarizing unit ARU may be interposed between the display panel DP and the coating window DW and may be overlapped with the transmission region TA and the bezel region BZA. The polarizing unit ARU may be bonded to the display panel DP by a first adhesive layer AM1. With reference to a side surface of the display panel DP which is adjacent to a side surface of the polarizing unit ARU, the side surface of the polarizing unit ARU may protrude further outward compared to the side surface of the display panel. In other words, the polarizing unit ARU may cover the display panel DP when viewed in a plan view. The width of the polarizing unit ARU in the first direction DR1 may be greater than the width of the display panel DP in the first direction DR1. The polarizing unit ARU extending in the first direction DR1 may serve as a base plate to form the light blocking pattern BM and the coating window DW.

The one side surface of the polarizing unit ARU may be aligned with one side surface, which is adjacent to the one side surface, of the coating window DW when viewed in a cross-sectional view. In other words, the one side surface of the polarizing unit ARU may be aligned in line with one side surface, which is adjacent to the one side surface, of the coating window DW when viewed in a cross-sectional view. Accordingly, the mutual separation between the polarizing unit ARU and the coating window DW by external impact may be minimized.

The polarizing unit ARU may include a first polarizing part ARU1 overlapped with the display panel DP flat and a second polarizing part ARU2 extending from the first polarizing part ARU1 in the first direction DR1 and in a direction opposite to the first direction DR1. An outer side surface of the second polarizing part ARU2 may protrude outward from an outer side surface, which is adjacent to the outer side surface of the second polarizing part ARU2, of the display panel DP. The second polarizing part ARU2 may be in a non-overlap state with the display panel DP.

As the first adhesive layer AM1 is disposed on a bottom surface of the polarizing unit ARU, the polarizing unit ARU may be bonded to the display panel DP.

The light blocking pattern BM may be directly disposed on the polarizing unit ARU and may correspond to the non-display region DP-NDA (see FIG. 2). The light blocking pattern BM may define the bezel region BZA. The light blocking pattern BM may be overlapped with a portion of the first polarizing part AR1 and the second polarizing part ARU2. Light blocking patterns BM may be disposed such that the light blocking patterns BM are adjacent to opposite sides of the transmission region TA. An outer side surface of the light blocking pattern BM may protrude from an outer side surface, which is adjacent to the outer side surface, of the display panel DP. Accordingly, a structure positioned under the light blocking pattern BM may be prevented from being viewed from the outside. The light blocking pattern BM may prevent a portion of light generated from the display panel DP from traveling to the outside through a region other than the transmission region TA.

The coating window DW may be directly disposed on the polarizing unit ARU and the light blocking pattern BM. The coating window DW may cover the light blocking pattern BM. The coating window DW may include a resin material which may be cured by irradiating the resin material with light. The coating window DW may be formed by applying the resin material and curing the resin material. A step difference corresponding to the light blocking pattern BM may be defined on a bottom surface of the coating window DW. A top surface of the coating window DW may be flat even though the step difference is defined on the bottom surface of the coating window DW. An outer side surface of the coating window DW may be aligned in line with an outer side surface of the polarizing unit ARU when viewed in a cross-sectional surface. The outer side surface of the coating window DW may be aligned in line with the outer side surface of the light blocking pattern BM and the outer side surface of the first adhesive layer AM1, when viewed in a cross-sectional view.

When the coating window DW is formed by applying the resin material and curing the resin material, the light blocking pattern BM may be difficult to be bonded to the rear surface of the coating window DW. In an example in which the coating window DW is applied and cured after the light blocking pattern BM is formed on the extending polarizing unit ARU according to the present disclosure, the light blocking pattern BM extending in the first direction DR1 from the display panel DP may be formed. In other words, the polarizing unit ARU extending in the first direction DR1 may serve as a base plate to fabricate the light blocking pattern BM and the coating window DW.

The coating window DW may include a first layer DW1, a second layer DW2, and a third layer DW3. The first layer DW1, the second layer DW2, and the third layer DW3 may be sequentially stacked in the third direction DR3. The first layer DW1, the second layer DW2, and the third layer DW3 may include the same material except for a photoinitiator. The photoinitiator may refer to a material including a smaller amount of resin material to initiate a polymerization reaction when receiving light (e.g., an ultraviolet ray). The photoinitiator may refer to a material to initiate curing in the process of curing the coating window DW.

The first layer DW1 may be directly disposed on the polarizing unit ARU and may include a first photoinitiator. The first layer DW1 may be lowered in a curing rate, as light is not deeply transmitted, when the light is irradiated into the front surface of the display device DD. Accordingly, the first layer DW1 may be formed to have a smaller thickness T1, and the first photoinitiator reacting with the light having a wavelength according to which the light may be transmitted may be utilized, thereby increasing the curing rate of the first layer DW1. The first photoinitiator may react with light having a first wavelength ranging from about 320 nm to about 400 nm to initiate the polymerization reaction.

The second layer DW2 may be directly disposed on the first layer DW1 and may include a second photoinitiator reacting with light having a second wavelength lower than the first wavelength of the light with which the first photoinitiator reacts. The thickness T2 of the second layer DW2 may be equal to or greater than the thickness T1 of the first layer DW1. The second layer DW2 may be disposed on the first layer DW1 and be subject to a curing reaction more smoothly than the first layer DW1, when the light is irradiated into the front surface of the display device DD. Even if the thickness T2 of the second layer DW2 may be greater than the thickness T1 of the first layer DW1, the curing reaction may be more smoothly made in the second layer DW2. Accordingly, the durability of the entire portion of the coating window DW may be improved by setting the thickness T2 of the second layer DW2 to be equal to or greater than the thickness T1 of the first layer DW1. The second photoinitiator included in the second layer DW2 may react with light having a wavelength ranging from about 280 nm to about 320 nm to initiate the polymerization reaction.

The third layer DW3 may be directly disposed on the second layer DW2 and may include a third photoinitiator reacting with light having a third wavelength smaller than the second wavelength of the light with which the second photoinitiator reacts. The thickness T3 of the third layer DW3 may be equal to or greater than the thickness T2 of the second layer DW2. The third layer DW3 may have the greatest curing reaction, as the third layer DW3 is closest to the front surface of the display device DD, when the light is irradiated onto the front surface of the display device DD. Even if the thickness T3 of the third layer DW3 may be greater than the thickness T2 of the second layer DW2, the curing reaction may be more smoothly made. Accordingly, the durability of the entire portion of the coating window DW may be improved by setting the thickness T3 of the third layer DW3 to be equal to or greater than the thickness T2 of the second layer DW2. The third photoinitiator included in the third layer DW3 may react with light having a wavelength ranging from about 280 nm or less to initiate the polymerization reaction.

The thickness T3 of the third layer DW3 may be equal to or greater than the thickness T2 of the second layer DW2, and the thickness T2 of the second layer DW2 may be equal to or greater than the thickness T1 of the first layer DW1. A ratio among the thickness T1 of the first layer DW1, the thickness T2 of the second layer DW2, and the thickness T3 of the third layer DW3 may be about 1:2:3. In an example in which the ratio of the thicknesses of the first to third layers DW1, DW2, and DW3 is about 1:2:3, the curing rate of the entire portion of the coating window DW may be uniform and the durability of the coating window DW may be improved. However, the ratio of the thickness may be varied as applicable or suitable in accordance with one or more embodiments of the present disclosure. In an example in which the thickness of the coating window DW is to be thinner, the thickness T1 of the first layer DW1, the thickness T2 of the second layer DW2, and the thickness T3 of the third layer DW3 may be substantially equal to each other.

As described herein, the first layer DW1 is disposed adjacent to the rear surface of the display device DD such that light for curing is difficult to be transmitted in the first layer DW1. Accordingly, to increase the curing rate of the first layer DW1, the thickness of the first layer DW1 may be reduced or a different photoinitiator may be used. Accordingly, the first layer DW1, the second DW2, and the third layer DW3 may each have a curing rate of about 90% or more. In an example in which the first layer DW1, the second DW2, and the third layer DW3 each have a curing rate of less than about 90%, as an uncured portion is delaminated, sticking and smearing may be caused. In some aspects, impact resistance may be lowered due to the deterioration of the physical properties.

The light transmittance of the coating window DW may be at least 90% with respect to the light of the whole wavelengths. In an example in which the light transmittance of the coating window DW is less than about 90%, a proportion, which is viewed by the user, of the light generated from the display panel DP may be reduced, such that light efficiency is lowered.

The pencil hardness of the coating window DW may be 9H or more. In this case, the pencil hardness may be measured in a manner in which when a load of a prescribed weight is applied to a pencil, and the pencil is scratched at an angle formed with the pencil, the concentration symbol of the hardest pencil not damaged is written as a result. In the curing process of the coating window DW according to an embodiment of the present disclosure, the coating window DW includes a plurality of layers, the layers are varied in the thicknesses and the types of the photoinitiators, such that the curing rate depending on a depth is uniformly obtained. Accordingly, the pencil hardness may be prevented from being lowered to less than 9H, as the rear surface of the coating window DW is not cured to cause a lower curing rate.

The modulus of elasticity of the coating window DW may be about 800 Mpa or more. In this case, the modulus of elasticity may be measured by a nano-indenter scheme. In other words, the modulus of elasticity may be obtained as the press-fitting depth based on the load is measured using the tip of a nanometer scale. As described herein, the rear surface of the coating window DW may be prevented from not being cured, thereby preventing the modulus of elasticity from being less than about 800 Mpa.

The entire thickness of the coating window DW may range 600 μm to about 1000 μm. According to an embodiment of the present disclosure, as the coating window DW ensures a stable curing rate, the coating window DW may ensure sufficient impact resistance and sufficient hardness even at the thickness of about 600 μm. In an example in which the thickness of the coating window DW is less than about 600 μm, the impact resistance of the coating window DW is insufficient. The terms “sufficient” and “insufficient” may respectively refer to a parameter (e.g., impact resistance, hardness) being equal to or greater than a threshold or being less than the threshold. Accordingly, when the impact is applied to the display panel DP disposed under the coating window DW, the display panel DP may be broken. In an example in which the thickness of the coating window DW exceeds about 1000 μm, the entire thickness of the display device DD may be unnecessarily thicker.

The first protective panel PF1 may be disposed on the bottom surface of the display panel DP to protect the display panel DP from the impact. The first protective panel PF1 may be bonded to the bottom surface of the display panel DP through the second adhesive layer AM2. However, the second adhesive layer AM2 may be omitted as applicable or suitable in accordance with one or more embodiments of the present disclosure.

The protective panel CP may be disposed on the bottom surface of the display panel DP. The protective panel CP may protect the display panel DP from the impact transmitted from the lower portion.

The protective panel CP may include a third adhesive layer AM3, a barrier layer BF, a fourth adhesive layer AM4, a cushion layer CU, and a fifth adhesive layer AM5. The barrier layer BF may be bonded to the bottom surface of the first protective layer PF1 through the third adhesive layer AM3. The barrier layer BF has a color having low light transmittance to prevent components, which are provided under the barrier layer BF, from being viewed.

The barrier layer BF may include a flexible synthetic resin film. For example, the barrier layer BF may be a film including polyimide (PI), or polyethylene terephthalate (PET). However, the material of the barrier layer BF is not limited thereto and may have various materials as applicable or suitable in accordance with one or more embodiments of the present disclosure.

The cushion layer CU may be bonded to the bottom surface of the barrier layer BF through the fourth adhesive layer AM4. The cushion layer CU may absorb impact transmitted from the lower portion of the display panel DP. The cushion layer CU may be a material, such as, for example, a foam sheet having a plurality of openings, having higher elasticity.

The support panel SSP may be disposed under the protective panel CP and support the display panel DP and the protective panel CP. The support panel SSP may include a metal plate having stiffness having a specific level or more. For example, the support panel SSP may be a stainless steel plate. The support panel SSP may have a black color to block external light incident to the display panel DP.

FIG. 5 is a cross-sectional view illustrating an enlarged region AA′ of FIG. 4 according to an embodiment of the present disclosure. More specifically, FIG. 5 is a view illustrating an extent in which light reacting with each of the first to third layers DW1, DW2, and DW3 is transmitted in a curing step.

Referring to FIG. 5, the third light L3 may more smoothly transmit through the coating window DW, compared to the first light L1 and the second light L2. The second light L2 may more smoothly transmit through the coating window DW, compared to the first light L1. As illustrated in FIG. 5, the first light L1 may reach the third layer DW3, the second light L2 may reach the second layer DW2, and the third light L3 may reach the first layer DW1. The first light L1 may have the wavelength of about 280 nm or less. The second light L2 may have the wavelength ranging about 280 nm from about 320 nm. The third light L3 may have the wavelength ranging about 320 nm from about 400 nm.

The first photoinitiator included in the first layer DW1 may react with the third light L3 to initiate the polymerization reaction. The second photoinitiator included in the second layer DW2 may react with the second light L2 to initiate the polymerization reaction. The third photoinitiator included in the third layer DW3 may react with the first light L1 to initiate the polymerization reaction.

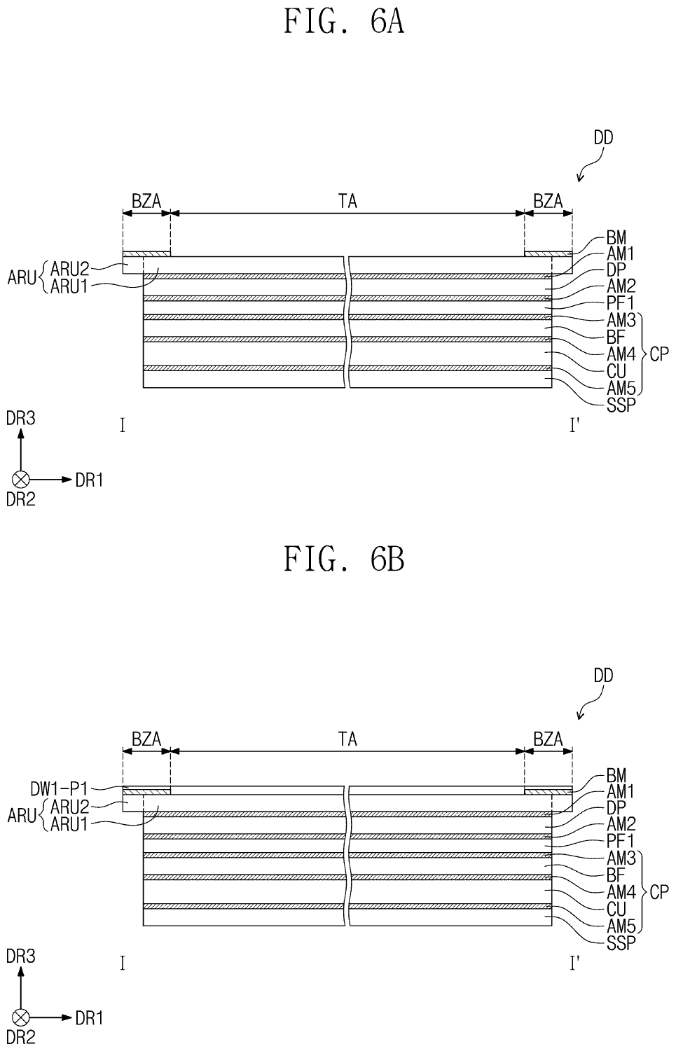

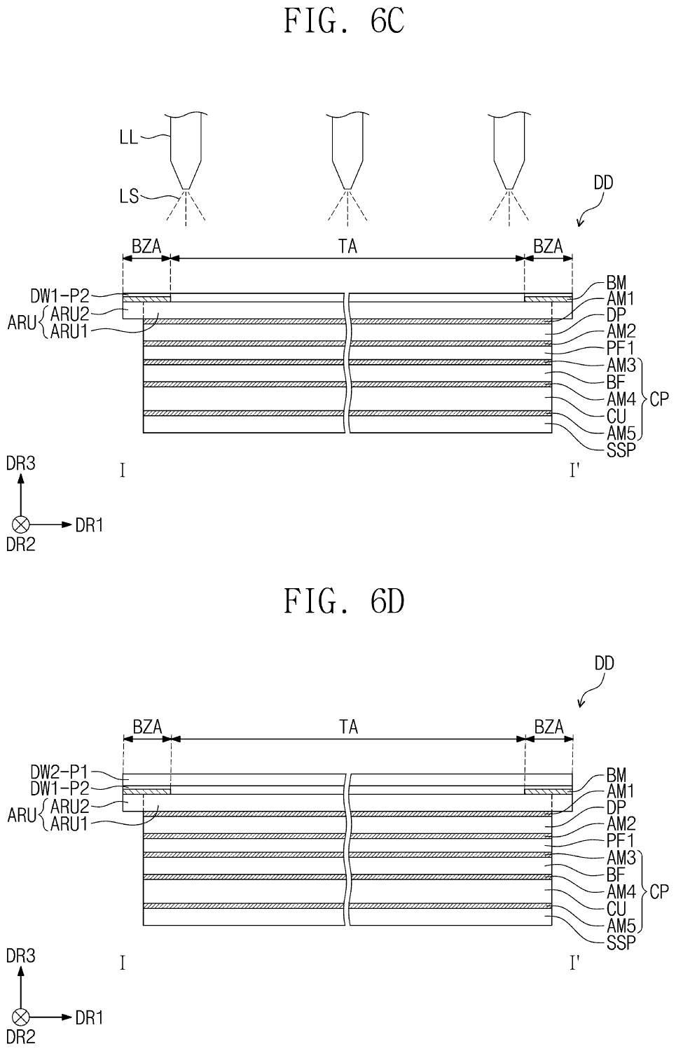

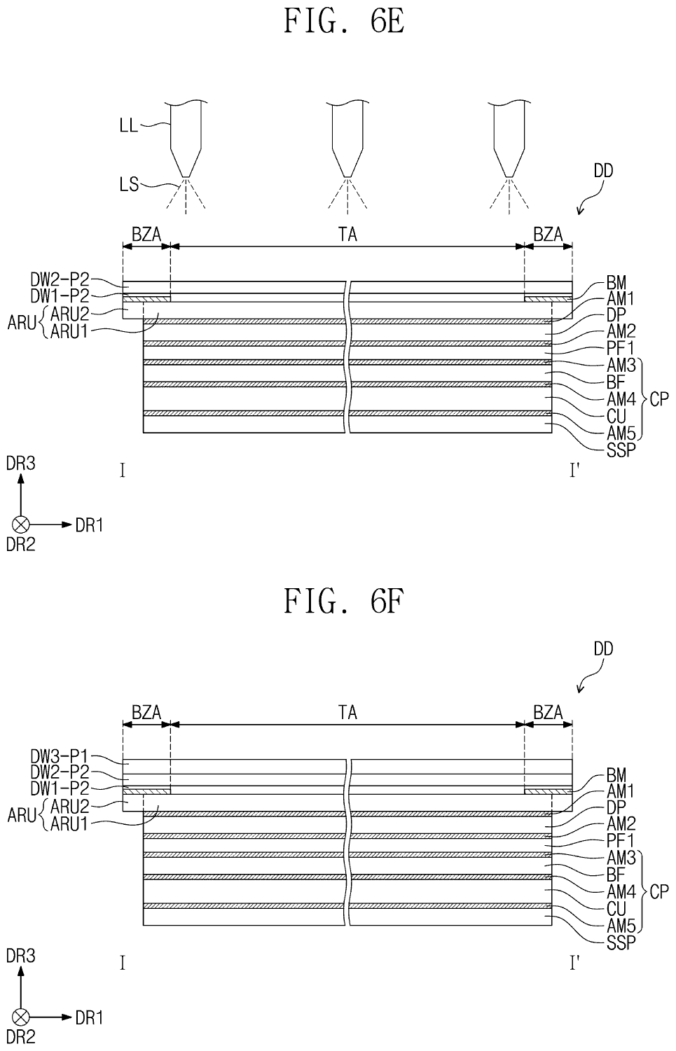

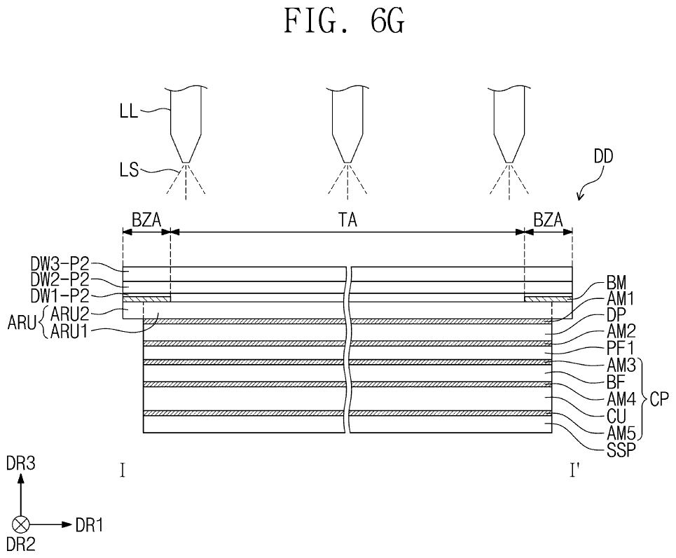

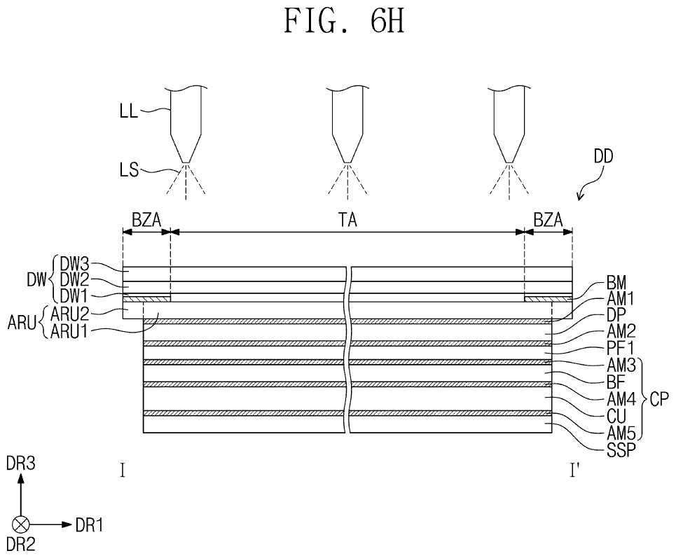

FIGS. 6A to 6H are cross-sectional views partially illustrating a method for manufacturing a display device according to an embodiment of the present disclosure. Hereinafter, the same components as components described with reference to FIGS. 1 to 5 will be assigned to the same reference numerals as those of the components described with reference to FIGS. 1 to 5, and the duplicated description will be omitted to avoid redundancy.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added.

Referring to FIG. 6A, the method may include preparing a preliminary device including the display panel DP, the polarizing unit ARU disposed on the display panel DP, and the light blocking pattern BM directly disposed on the polarizing unit ARU and overlapped with the bezel region BZA. The polarizing unit ARU may include the second polarizing part ARU2 protruding outward, and the light blocking pattern BM may be formed on the second polarizing part ARU2 such that the light blocking pattern BM protrudes outward from the display panel DP.

Referring to FIG. 6B, the method may include applying, to the polarizing unit ARU, a first coating liquid DW1-P1 including the first photoinitiator and a resin material curable by irradiating the resin material with light. The polarizing unit ARU may serve as a base substrate to apply the first coating liquid DW1-P1. The first coating liquid DW1-P1 may cover the light blocking pattern BM.

Referring to FIG. 6C, the method may include forming a first preliminary coating layer DW1-P2 by pre-curing the first coating liquid DW1-P1 (see FIG. 6B) applied. In this case, light LS generated from an exposing device LL additional may be utilized. In this case, the light LS may be an ultraviolet ray. The light LS used in the step of pre-curing the first coating liquid DW1-P1 may have the energy of about 100 mJ or less. In the step of pre-curing the first coating liquid DW1-P1, the first coating liquid DW1-P1 may be cured to the extent that a second coating liquid DW2-P1 (see FIG. 6D) is applied onto the first preliminary coating layer DW1-P2.

Referring to FIG. 6D, the method may include applying the second coating liquid DW2-P1, which includes the second photoinitiator, which reacts with light having the second wavelength less than the first wavelength of the light with which the first photoinitiator reacts, and the resin material to the first preliminary coating layer DW1-P2. The first preliminary coating layer DW1-P2 may serve as a base substrate to apply the second coating liquid DW2-P1.

Referring to FIG. 6E, the method may include forming a second preliminary coating layer DW2-P2 by pre-curing the second coating liquid DW2-P1 (see FIG. 6B) applied. In this case, the light LS generated from the exposure device LL additional may be utilized. The light LS used in the step of pre-curing the second coating liquid DW2-P1 may have the energy of about 100 mJ or less. In the step of pre-curing the second coating liquid DW2-P1, the second coating liquid DW2-P1 may be cured to the extent that a third coating liquid DW3-P1 (see FIG. 6F) is applied onto the second preliminary coating layer DW2-P2.

Referring to FIG. 6F, the method may include applying the third coating liquid DW3-P1, which includes the third photoinitiator, which reacts with light having the third wavelength less than the second wavelength of the light with which the second photoinitiator reacts, and the resin material to the second preliminary coating layer DW2-P2. The second preliminary coating layer DW2-P2 may serve as a base substrate to apply the third coating liquid DW3-P1.

Referring to FIG. 6G, the method may include forming a third preliminary coating layer DW3-P2 by pre-curing the third coating liquid DW3-P1 (see FIG. 6F) applied. In this case, the light LS generated from the additional exposure device LL may be utilized. The light LS used in the step of pre-curing the third coating liquid DW3-P1 may have the energy of about 100 mJ or less.

Referring to FIG. 6H, the method may include performing a main curing step with respect to the first preliminary coating layer DW1-P2, the second preliminary coating layer DW2-P2, and the third preliminary coating layer DW3-P2 in association with forming the coating window DW including the first layer DW1, the second layer DW2, and the third layer DW3. Light LS used in the main curing step may have the energy of about 1200 mJ or less. Since the light LS irradiates the front surface of the display device DD, the first layer DW1 positioned at a longer distance from the front surface may not be cured. As described herein, the curing rate of the first layer DW1 may be increased by reducing the thickness of the first layer DW1 such that the first photoinitiator reacting with the light having the wavelength reaching the deepest part is included in the first layer DW1.

According to the present disclosure, the display device may include the first layer including the first photoinitiator and the second layer including the second photoinitiator which reacts with light having a wavelength less than a wavelength of light with which the first photoinitiator reacts. Accordingly, the layer close to the rear surface of the coating window may include a photoinitiator reacting with the light having the higher wavelength reaching the deep portion of the resin material. Accordingly, the physical characteristic is prevented from being deteriorated, as the front surface of the coating window is first cured such that the rear surface of the coating window is not cured.

Although embodiments of the present disclosure have been described for illustrative purposes, those skilled in the art will appreciate that various modifications, and substitutions are possible, without departing from the scope and spirit of the invention as disclosed in the accompanying claims. Accordingly, the technical scope of the present disclosure is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display panel comprising a display region and a non-display region surrounding the display region;
a polarizing unit disposed on the display panel and covering the display panel, when viewed in a plan view; and
a coating window directly disposed on the polarizing unit and comprising a resin material cured by irradiating the resin material with light,
wherein the coating window comprises:
a first layer directly disposed on the polarizing unit and comprising a first photoinitiator which reacts with light having a first wavelength; and
a second layer directly disposed on the first layer and comprising a second photoinitiator which reacts with light having a second wavelength shorter than the first wavelength.

2. The display device of claim 1, wherein the second layer has a thickness equal to or greater than a thickness of the first layer.

3. The display device of claim 1, wherein the coating window further comprises:
a third layer directly disposed on the second layer and comprising a third photoinitiator which reacts with light having a third wavelength shorter than the second wavelength.

4. The display device of claim 3, wherein the third layer has a thickness equal to or greater than a thickness of the second layer.

5. The display device of claim 3, wherein a ratio among a thickness of the first layer, a thickness of the second layer, and a thickness of the third layer is about 1:2:3.

6. The display device of claim 3, wherein a thickness of the first layer, a thickness of the second layer, and a thickness of the third layer are substantially equal to each other.

7. The display device of claim 1, wherein:
the first wavelength of the light which the first photoinitiator reacts with ranges from about 320 nm to about 400 nm, and
the second wavelength of the light which the second photoinitiator reacts with ranges from about 280 nm to about 320 nm.

8. The display device of claim 3, wherein the third photoinitiator reacts with light having a wavelength of about 280 nm or less.

9. The display device of claim 1, wherein the polarizing unit comprises:
a first polarizing part overlapped with the display panel when viewed in the plan view; and
a second polarizing part extending from the first polarizing part and having an outer side surface protruding further outward compared to an outer side surface of the display panel.

10. The display device of claim 1, further comprising:
a light blocking pattern directly disposed on the polarizing unit and corresponding to the non-display region,
wherein the coating window directly contacts the light blocking pattern and covers the light blocking pattern.

11. The display device of claim 1, wherein the coating window has a light transmittance of at least about 90% with respect to light of whole wavelengths.

12. The display device of claim 1, wherein the coating window has a pencil hardness of at least 9H.

13. The display device of claim 3, wherein a curing rate of the first layer, a curing rate of the second layer, and a curing rate of the third layer are each at least about 90%.

14. The display device of claim 1, wherein the coating window has a thickness ranging from about 600 μm to about 1000 μm.

15. The display device of claim 1, wherein an elastic modulus of the coating window is at least about 800 Mpa.

16. A method for manufacturing a display device, the method comprising:
preparing a preliminary display device comprising a display panel and a polarizing unit disposed on the display panel, wherein the display panel comprises a display region and a non-display region surrounding the display region;
applying a first coating liquid on the polarizing unit, wherein the first coating liquid comprises a first photoinitiator and a resin material curable by irradiating the resin material with light, and the first photoinitiator reacts with light having a first wavelength;
forming a first preliminary coating layer by pre-curing the first coating liquid;
applying a second coating liquid on the first preliminary coating layer, wherein the second coating liquid comprises a second photoinitiator and the resin material, and the second photoinitiator reacts with light having a second wavelength shorter than the first wavelength;
forming a second preliminary coating layer by pre-curing the second coating liquid; and
forming a first layer and a second layer by performing a main curing with respect to the first preliminary coating layer and the second preliminary coating layer.

17. The method of claim 16, further comprising:
applying a third coating liquid on the second preliminary coating layer, wherein the third coating liquid comprises a third photoinitiator and the resin material, and the third photoinitiator reacts with light having a third wavelength shorter than the second wavelength; and
forming a third preliminary coating layer by pre-curing the third coating liquid,
wherein the main curing is performed further with respect to the third preliminary coating layer and forms a third layer.

18. The method of claim 16, wherein:
light having energy of about 100 mJ or less is utilized in each of the pre-curing of the first coating liquid and the pre-curing of the second coating liquid, and light having energy of about 1,200 mJ or more is utilized in the main curing.

19. The method of claim 17, wherein:
the second layer has a thickness equal to or greater than a thickness of the first layer; and
the third layer has a thickness equal to or greater than the thickness of the second layer.

20. An electronic device comprising:
a display module; and
a coating window comprising a resin material cured by irradiating the resin material with light and disposed on the display module,
wherein:
the display module comprises:
a display panel comprising a display region and a non-display region surrounding the display region; and
a polarizing unit disposed on the display panel and covering the display panel, when viewed in a plan view, and
the coating window comprises:
a first layer directly disposed on the polarizing unit and comprising a first photoinitiator which reacts with light having a first wavelength; and
a second layer directly disposed on the first layer and comprising a second photoinitiator which reacts with light having a second wavelength shorter than the first wavelength.
